(19) United States
(12) Patent Application Publication
(10) Pub. No.: US 2021/0310348 A1
(43) Pub. Date: Oct. 7, 2021

(54) WIDE FIELD-OF-VIEW CHARGED PARTICLE FILTER

(71) Applicant: THERMO ELECTRON SCIENTIFIC INSTRUMENTS LLC, Madison, WI (US)

(72) Inventors: Justin Morrow, Madison, WI (US); Steven FOOTE, Middleton, WI (US)

(21) Appl. No.: 17/217,747

(22) Filed: Mar. 30, 2021

Related U.S. Application Data
(60) Provisional application No. 63/003,575, filed on Apr. 1, 2020.

(51) Int. Cl. E21B 47/022; H01J 37/147; H01J 37/32

(52) U.S. Cl. CPC E21B 47/022; H01J 37/32642; H01J 37/1475

(57) ABSTRACT

An embodiment of a charged particle filter is described that comprises a plurality of magnets, each having a surface sloped at an angle relative to a plane defined by a line from a center of a field of view on a detector to the center of a field of view on a platform. In the described embodiment, the sloped surfaces are positioned to form a bore that comprises a magnetic field gradient that is strongest at a first aperture on a side of the bore proximate to the detector.

### CROSS-REFERENCE TO RELATED APPLICATIONS

The present application claims the priority benefit from U.S. Patent Application Ser. No. 63/003,575, filed Apr. 1, 2020, which is hereby incorporated by reference herein in its entirety for all purposes.

### FIELD OF THE INVENTION

The present invention is generally directed to a charged particle filter configured to maximize the field strength within the filter without impinging on the field-of-view.

### BACKGROUND

It is generally appreciated that charged particle filters (also sometimes referred to as “electron traps” or “magnetic deflectors”) are widely used with energy dispersive x-ray spectroscopy (EDS) systems that detect x-ray photons emitted from a material exposed to an electron beam. The detected x-ray photons are generally used to characterize the elemental composition of the material. It is also generally appreciated that the electron beam produces back scattered electrons (e.g. charged particles) that produce similar signals to the x-ray photons causing undesirable background noise in the signal data.

Typical embodiments of charged particle filters are configured to substantially reduce or prevent the charged particles from reaching the detector by producing a magnetic field with a sufficiently high field strength. In general, the EDS systems are utilized in microscopy applications, such as in a Scanning Electron Microscope (SEM), where a compact geometry of the charged particle filter is highly desirable due to the confined space within the microscope. Examples of charged particle filters for use in microscopy applications are described in U.S. Pat. Nos. 9,697,984 and 9,837,242, each of which is hereby incorporated by reference herein in its entirety for all purposes.

In typical microscopy applications, the compact geometry comprises a small field of view that is compatible with the small scan areas associated with the microscopy applications (e.g. 1 mm×1 mm). However, that small field of view is detrimental for use with other applications such as, for example, in electron-beam additive manufacturing (EBAM) applications implemented by what is referred to as an electron beam melting or electron-beam powder bed fusion instrument. EBAM instruments generally include large scan areas (e.g. 0.2 meter×0.2 meter). However, simply creating an oversized particle filter with a large aperture having a large field of view will have insufficient filed strength to effectively prevent charged particles from reaching the detector. This is especially problematic with EBAM applications because the charged particles in EBAM typically have an energy of 60 keV, twice as high as the normal maximum value of 30 keV in a SEM.

Therefore, a need exists for a charged particle filter with a wide field of view with sufficient field strength to effectively prevent charged particles from reaching the detector.

### SUMMARY

Systems, methods, and products to address these and other needs are described herein with respect to illustrative, non-limiting, implementations. Various alternatives, modifications and equivalents are possible.

An embodiment of a charged particle filter is described that comprises a plurality of magnets, each having a surface sloped at an angle relative to a plane defined by a line from a center of a field of view on a detector to the center of a field of view on a platform. In the described embodiment, the sloped surfaces are positioned to form a bore that comprises a magnetic field gradient that is strongest at a first aperture on a side of the bore proximate to the detector.

Depending on the implementation the sloped surfaces may be substantially planar or substantially conical where the radius of the substantially conical surface is relative to the angle. Also, in some implementations the sloped surfaces comprise an angle in the range of 5-45°, and more specifically may include an angle of 15.4°.

Further, the bore may have a field of view on the platform defined by a diameter of a second aperture on a side of the bore facing the platform. In some cases, the field of view is about 128 mm in diameter. Also, the magnetic field gradient may include a range of magnetic field strength that is about 1000 gauss-5000 gauss.

Additionally, in some cases the charged particle filter may include one or more inserts configured to fill space between the magnets. Similarly, in some cases the charged particle filter may include a flux ring with a geometry that properly positions the magnets for the slope angle.

An embodiment of an electron-beam additive manufacturing instrument is also described that, comprises an electron beam source configured to produce an electron beam; a platform configured as a support upon which the electron beam additive manufacturing instrument builds a product in response to the electron beam; a detector configured to produce a signal in response to one or more X-ray photons released from the product in response to the electron beam; and a charged particle filter configured to deflect one or more charged particles released from the product in response to the electron beam away from the detector, wherein the charged particle filter comprises a plurality of magnets, each comprising a surface sloped at an angle relative to a plane defined by a line from a center of a field of view on a detector to the center of a field of view on a platform. Further, the sloped surfaces are positioned to form a bore that comprises a magnetic field gradient that is strongest at a first aperture on a side of the bore proximate to the detector.

Depending on the implementation the sloped surfaces may be substantially planar or substantially conical where the radius of the substantially conical surface is relative to the angle. Also, in some implementations the sloped surfaces comprise an angle in the range of 5-45°, and more specifically may include an angle of 15.4°.

Further, the bore may have a field of view on the platform defined by a diameter of a second aperture on a side of the bore facing the platform. In some cases, the field of view is about 128 mm in diameter. Also, the magnetic field gradient may include a range of magnetic field strength that is about 1000 gauss-5000 gauss.

Additionally, in some cases the charged particle filter may include one or more inserts configured to fill space between the magnets. Similarly, in some cases the charged particle filter may include a flux ring with a geometry that properly positions the magnets for the slope angle.

The above embodiments and implementations are not necessarily inclusive or exclusive of each other and may be combined in any manner that is non-conflicting and otherwise possible, whether they are presented in association with a same, or a different, embodiment or implementation. The description of one embodiment or implementation is not intended to be limiting with respect to other embodiments and/or implementations. Also, any one or more function, step, operation, or technique described elsewhere in this specification may, in alternative implementations, be combined with any one or more function, step, operation, or technique described in the summary. Thus, the above embodiment and implementations are illustrative rather than limiting.

### BRIEF DESCRIPTION OF THE DRAWINGS

The above and further features will be more clearly appreciated from the following detailed description when taken in conjunction with the accompanying drawings. In the drawings, like reference numerals indicate like structures, elements, or method steps and the leftmost digit of a reference numeral indicates the number of the figure in which the references element first appears (for example, element 110 appears first in FIG. 1). All of these conventions, however, are intended to be typical or illustrative, rather than limiting.

FIG. 1 is a functional block diagram of one embodiment of an electron-beam additive manufacturing instrument in communication with a computer;

FIG. 2 is a simplified graphical representation of one embodiment of the electron-beam additive manufacturing instrument of FIG. 1 with a charged particle filter;

FIG. 3 is a simplified graphical representation of one embodiment of the charged particle filter of FIG. 2 with a plurality of magnets;

FIG. 4A is a simplified graphical representation of one embodiment of the charged particle filter of FIG. 2 with the plurality of magnets arranged to provide a slope angle;

FIG. 4B is a simplified graphical representation of one embodiment of the charged particle filter of FIG. 2 where each of the plurality of magnets have a geometry that includes a slope angle;

FIG. 5A is a simplified graphical representation of one embodiment of the charged particle filter of FIG. 2 with a flux ring that properly positions the plurality of magnets; and

FIG. 5B is a simplified graphical representation of one embodiment of the charged particle filter of FIG. 2 with a flux ring and the plurality of magnets include a substantially conical surface that includes a slope angle within a bore.

Like reference numerals refer to corresponding parts throughout the several views of the drawings.

### DETAILED DESCRIPTION OF EMBODIMENTS

As will be described in greater detail below, embodiments of the described invention include a charged particle filter with a wide field of view and comprising sufficient field strength to effectively prevent charged particles from reaching a detector. More specifically, the charged particle filter is configured with a plurality of magnets having a sloped surface relative to a plane parallel to particle travel where the space between the magnets decreases from a side of the charged particle filter closest to the source of the charged particles to a side closest to a detector.

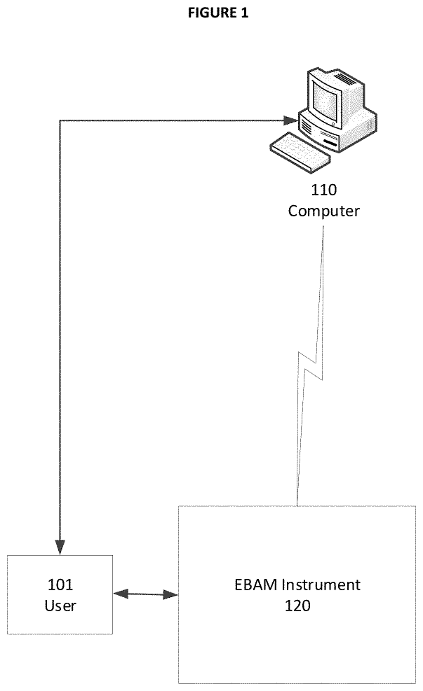

FIG. 1 provides a simplified illustrative example of user 101 capable of interacting with computer 110 and EBAM Instrument 120. Embodiments of EBAM Instrument 120 may include a variety of commercially available EBAM Instruments. For example, EBAM Instrument 120 may include the Q10 electron beam melting instrument available from Arcam AB (a GE Additive company). FIG. 1 also illustrates a network connection between computer 110 and EBAM Instrument 120, however it will be appreciated that FIG. 1 is intended to be exemplary and additional or fewer network connections may be included. Further, the network connection between the elements may include “direct” wired or wireless data transmission (e.g. as represented by the lightning bolt) as well as “indirect” communication via other devices (e.g. switches, routers, controllers, computers, etc.) and therefore the example of FIG. 1 should not be considered as limiting.

Computer 110 may include any type of computing platform such as a workstation, a personal computer, a tablet, a “smart phone”, one or more servers, compute cluster (local or remote), or any other present or future computer or cluster of computers. Computers typically include known components such as one or more processors, an operating system, system memory, memory storage devices, input-output controllers, input-output devices, and display devices. It will also be appreciated that more than one implementation of computer 110 may be used to carry out various operations in different embodiments, and thus the representation of computer 110 in FIG. 1 should not be considered as limiting.

In some embodiments, computer 110 may employ a computer program product comprising a computer usable medium having control logic (e.g. computer software program, including program code) stored therein. The control logic, when executed by a processor, causes the processor to perform some or all of the functions described herein. In other embodiments, some functions are implemented primarily in hardware using, for example, a hardware state machine. Implementation of the hardware state machine so as to perform the functions described herein will be apparent to those skilled in the relevant arts. Also in the same or other embodiments, computer 110 may employ an internet client that may include specialized software applications enabled to access remote information via a network. A network may include one or more of the many types of networks well known to those of ordinary skill in the art. For example, a network may include a local or wide area network that may employ what is commonly referred to as a TCP/IP protocol suite to communicate. A network may include a worldwide system of interconnected computer networks that is commonly referred to as the internet, or could also include various intranet architectures. Those of ordinary skill in the related art will also appreciate that some users in networked environments may prefer to employ what are generally referred to as “firewalls” (also sometimes referred to as Packet Filters, or Border Protection Devices) to control information traffic to and from hardware and/or software systems. For example, firewalls may comprise hardware or software elements or some combination thereof and are typically designed to enforce security policies put in place by users, such as for instance network administrators, etc.

As described herein, embodiments of the described invention include a charged particle filter with a plurality of magnets comprising a wide field of view and comprising sufficient field strength to effectively prevent charged particles from reaching a detector. In the described embodiments, the charged particle filter has a surface sloped at an angle relative to a plane defined by a line from the center of a field of view on a detector to the center of a field of view on a platform, where the sloped surface produces a gradient of field strength with the strongest field strength in the region of the charged particle filter proximal to a detector.

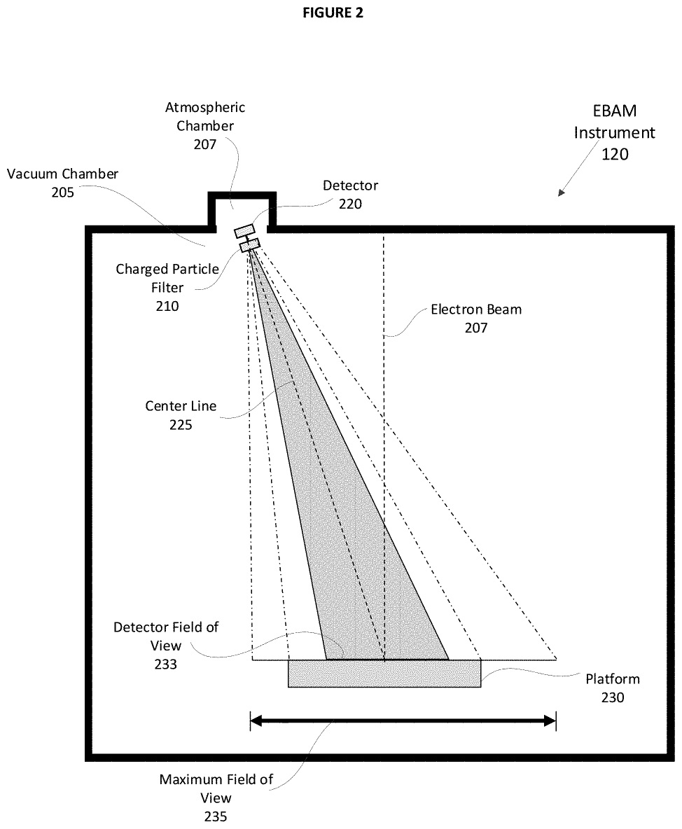

FIG. 2 provides a simplified illustrative example of EBAM instrument 120 that comprises charged particle filter 210 and detector 220. In some embodiments detector 220 may include what is referred to as a Silicon Drift Detector (SDD), or other type of detector known in the related art. Also, in some embodiments charged particle filter is positioned within vacuum chamber 205 that comprises a vacuum environment typically employed with electron-beam additive manufacturing applications. Also, in the same or alternative embodiments detector 220 is positioned within atmospheric chamber 207 that comprises an environment that is substantially similar to the ambient environment outside of EBAM instrument 120. For example, charged particle filter 210 and detector 220 may be positioned in different environments separated by a gas tight partition that is transmissive to x-ray photons (e.g. a “window”). In some embodiments, it is desirable that the partition is thin, thus allowing low energy X-ray photons to pass, in some cases supported by an additional structure to provide rigidity. Typical partitions used in EDS applications may be constructed of polymer based materials, Beryllium (Be), or Sodium (Na). However, any type of partition with desirable characteristics may be used. Also in the present example, in typical electron-beam additive manufacturing applications, electron beam 207 originates from directly above platform 230 (e.g. electron beam 207 may be substantially perpendicular to the plane of platform 230, however it will be appreciated that electron beam 207 is under directional control of computer 110 to build products and may be directed at angles past perpendicular). Further, detector 220 and charged particle filter 210 are both positioned to one side of vacuum chamber 205 with a direct line of sight to platform 230, with both tilted at an angle, which depends on the distance from the position of origination of electron beam 207, to provide detector field of view 233 to the region of platform 230 where electron beam 207 is used to build products. In many embodiments, the position detector 220 and charged particle filter 210 is limited to the available ports on vacuum chamber 205.

FIG. 2 also illustrates center line 225 that defines a plane from a center of a field of view on detector 220 to the center of a field of view on a platform 230. In some embodiments centerline 225 defines a distance between charged particle filter 210 to platform 230 that is also related to the height distance of electron beam 207 that is defined by a distance between the top of platform 230 (e.g. the support upon which EBAM 120 builds products) to the top of vacuum chamber 205. For example, center line 225 may include a distance of about 472 mm and electron beam 207 may include a height distance of about 450 mm. However, it will be appreciated that EBAM 120 may include a variety of configurations and dimensions, and thus the dimensions in the present example should not be considered as limiting.

Additionally, FIG. 2 illustrates that detector field of view 233 is smaller than maximum field of view 235. In the embodiments described herein, maximum field of view 235 is defined by characteristics of charged particle filter 210 and detector field of view 233 is defined by characteristics of one or more other elements, where in some instances it may be desirable that detector field of view 233 is not at the limit of maximum field of view 235. Alternatively, in some applications it may be desirable that detector field of view 233 is substantially the same as maximum field of view 235. For example, in some embodiments detector field of view may include an area that is about 128 mm in diameter and maximum field of view may include an area that is about 316 mm in diameter. Also in some cases platform 230 may include an area that is about 200 mm in diameter, or in width where embodiments of platform 230 are substantially square or rectangular.

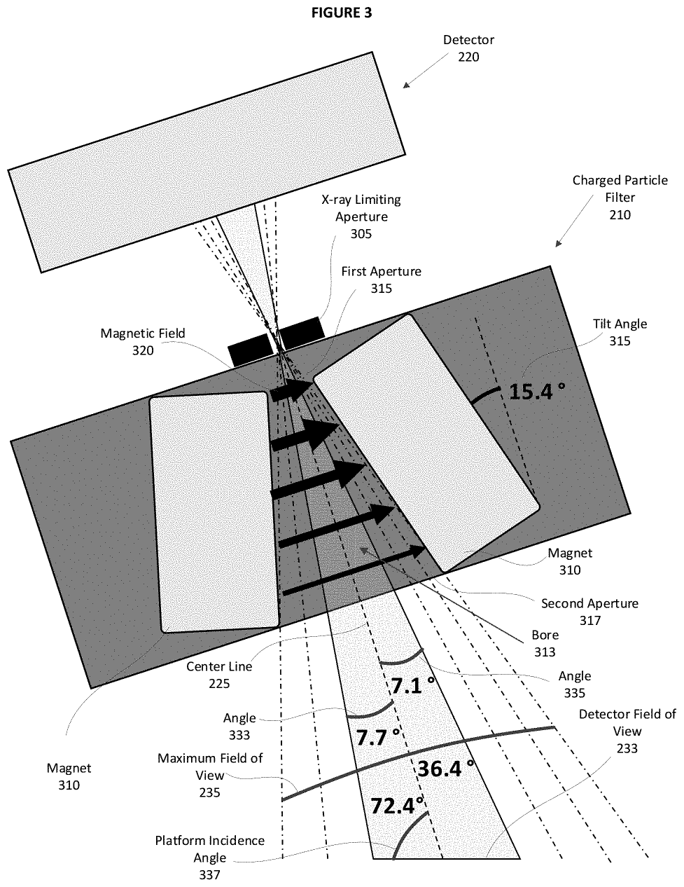

FIG. 3 provides a simplified illustrative example of a magnified view of charged particle filter 210 and detector 220 of FIG. 2. First, FIG. 3 illustrates X-ray limiting aperture 305 that selectively limits the number of X-ray photons that strike detector 220. In some embodiments, X-ray limiting aperture 305 selects X-ray photons from detector field of view 233 that is associated with the area being excited by electron beam 207, thus reducing the detection of X-ray photons originating from other parts of vacuum chamber 205 that could contribute to noise in the signal. Importantly, in the described embodiments charged particle filter 210 substantially reduces or eliminates detection of charged particles originating from the entire region of maximum field of view 235 that can be a source of noise in the detected signal.

In some embodiments, X-ray limiting aperture 305 may also reduce the number of photons that strike detector 220, which has the benefit of reducing the likelihood of saturation or damaging elements of detector 220. Also, it will be appreciated that some embodiments of EBAM instrument 120 may allow a user to change the dimension of X-ray limiting aperture 305 enabling use of different volumes of detector field of view 233.

FIG. 3 further illustrates a plurality of magnets 310, each with a surface sloped at an angle relative to center line 225 where the sloped surfaces define bore 313 through which X-ray photons pass. Magnets 310 may include any type of magnet typically used in the art such as neodymium or other type of magnet with desirable characteristics. For example, permanent magnets constructed from materials with various grades of SmCo and primarily grades of NdFe may be employed.

In the embodiment of FIG. 3 magnets 310 are substantially rectangular with substantially parallel surfaces, where tilt angle 315 is substantially the same as the angle of slope of the surfaces of bore 313. In the example of FIG. 3, the slope angle is equal to about 15.4°, however a slope angle in the range of 5-45° is considered within the scope of the invention.

In the described embodiments, the position of magnets 310 define the area of maximum field of view 235, and more specifically particular portions of magnets 310 define the area of maximum field of view 235 depending on the degree of the slope angle. For example, for a slope angle of about 15.4° as illustrated in FIG. 3, the corner of each magnet 310 within bore 313 at second aperture 317 that faces platform 230 (e.g. where the X-ray photons and charged particles originate) defines the area of maximum field of view 235. Alternatively, for small slope angles (e.g. <10°) the corner of each magnet 310 within bore 313 at first aperture 315 that is proximal to detector 220 defines the area of maximum field of view 235.

In the example of FIG. 3, maximum field of view 235 is 36.4°, however maximum field of view can include a field of view in the range of 10-90°. Further, due to the tilt angle of detector 220 and charged particle filter 210 (as described above), center line 225 interacts with platform 230 at platform incidence angle 337 which may include an angle of 72.4°. Also, due to the tilt angle of detector 220 and charged particle filter 210 the angles measured from center line 225, namely angle 333 (e.g. 7.7°) and angle 335 (e.g. 7.1°), are slightly different. Further, those of ordinary skill in the art will appreciate that the example of FIG. 3 shows a symmetric configuration with similar slope values for both magnets 310 that lead to different field of view angles 333 and 335. However, if it is desired that angles 333 and 335 be similar (or any other values), this could be achieved with magnets 310 independently having a slope configuration comprising an asymmetric design (e.g. each magnet 310 having a different slope angle from the other).

FIG. 3 also illustrates magnetic field 320 that comprises a gradient that is strongest at first aperture 315 on a side of bore 313 proximate to detector 220 and weakest at second aperture 317 on a side of bore 313 facing platform 230 (e.g. magnetic field strength illustrated in FIG. 3 by the thickness of the arrows). In the described embodiments, the spacing between magnets 310 that defines aperture 315, or diameter of aperture 315 where it applies in certain embodiments. Those of ordinary skill in the art will appreciate that the magnetic field strength is proportional to the strength of magnets 310 and the distance between them. Also, magnetic field 320 must include sufficient field strength to efficiently deflect charged particles, however the field strength should not be so strong such that it influences electron beam 207 or significantly affects the operation of detector 220 as the charged particles migrating inside detector 220 could be influenced by magnetic field 320 if the field strength is excessively high. For example, magnetic field 320 may include a gradient of magnetic field strength in the range of about 1000 gauss-5000 gauss (e.g. from second aperture 317 to first aperture 315). However, it will be appreciated that the field strength depends on a variety of factors such as the grade of material used for magnets 310, and thus the example should not be considered as limiting.

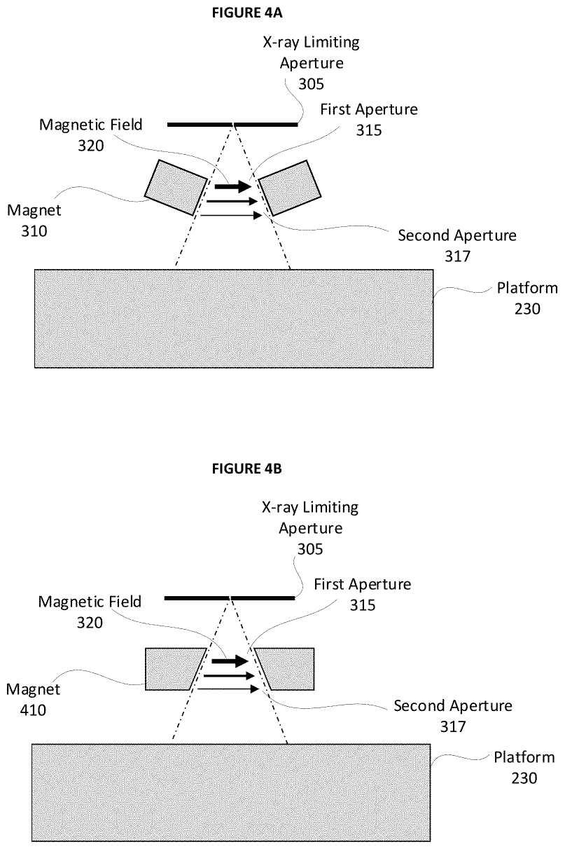

FIG. 4A provides a simplified graphical example of the substantially rectangular configuration of magnets 310 where each embodiment of magnet 310 is tilted to provide the slope angle, as described above. However, it will be appreciated that other configurations are also considered to be within the scope of the described invention. One such example is illustrated in FIG. 4B as magnet 410 that includes a geometry with the slope angle incorporated into the configuration. For example, magnet 410 does not require that it is configured in a specific position within charged particle filter 210. Rather, magnet 410 can be designed to accommodate any position thus allowing design freedom for charged particle 210. Further, as illustrated in FIG. 4B, magnet 410 is substantially thicker (e.g. wider) at the first aperture 315 and thus has great magnetic field strength than at second aperture 317 that has less thickness.

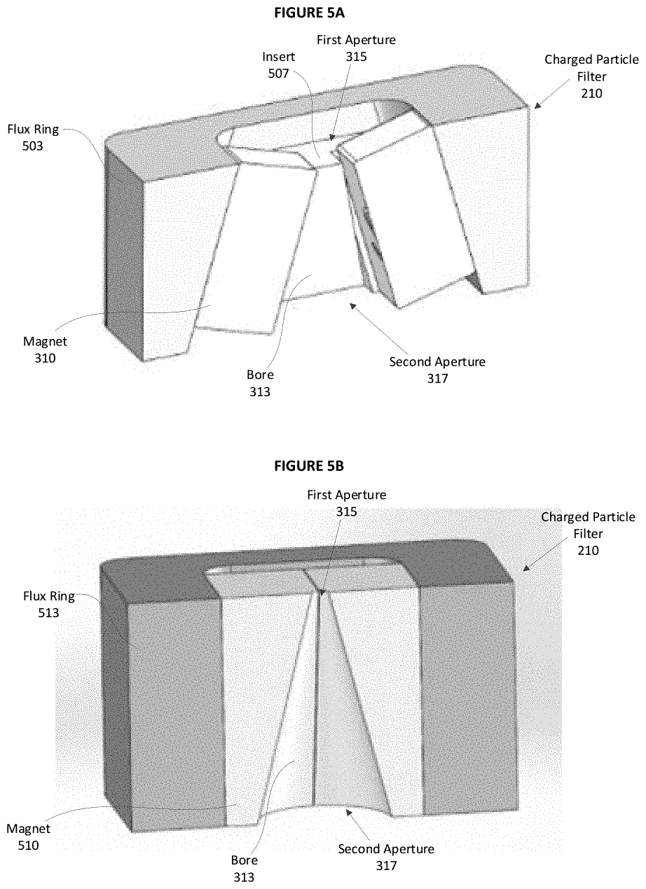

FIG. 5A illustrates a cutaway view (e.g. about half) of an embodiment of charged particle filter 210 that comprises magnets 310, as described above. FIG. 5A also illustrates flux ring 503 that comprises a geometry that properly positions magnets 310 for the desired slope angle. In some embodiments flux ring 503 may be constructed of steel, or other desirable material. For example, flux ring 503 may be constructed from any suitable ferromagnetic permeable material which may vary depending on space availability, location to other sensitive items effected by magnetic field 320, or other factors. In the present example, specific materials may include sintered cobalt (250), or a mild steel (2,000), although various specialty grades of steel may be used.

Further, FIG. 5A illustrates insert 507 that fills space between magnets 310 but does not interfere with bore 313 or apertures 315 and 317. In some embodiments, charged particle filter 210 may include multiple implementations of insert 507 that may be constructed of aluminum, or other desirable material. For example, insert 510 should be constructed from a non-magnetic or paramagnetic material. Typically, the materials for insert 510 should include a light element to minimize x-ray generation such as aluminum or carbon.

FIG. 5B illustrates a cutaway view (e.g. about half) of another embodiment of charged particle filter 210 that comprises magnets 510, that include a curved geometry of the surface comprising the slope angle. In the described embodiment, the plurality of magnets form a substantially conical surface with the slope angle in bore 313. The embodiment illustrated in FIG. 5B, may or may not include insert elements similar to insert 507 described for FIG. 5A, as well as flux ring 513 with a geometry that properly positions magnets 510.

Having described various embodiments and implementations, it should be apparent to those skilled in the relevant art that the foregoing is illustrative only and not limiting, having been presented by way of example only. Many other schemes for distributing functions among the various functional elements of the illustrated embodiments are possible. The functions of any element may be carried out in various ways in alternative embodiments

What is claimed is:

1. A charged particle filter, comprising:
A plurality of magnets, each comprising a surface sloped at an angle relative to a plane defined by a line from a center of a field of view on a detector to the center of a field of view on a platform, wherein the sloped surfaces are positioned to form a bore that comprises a magnetic field gradient that is strongest at a first aperture on a side of the bore proximate to the detector.

2. The charged particle filter of claim 1, wherein:
the sloped surfaces are substantially planar.

3. The charged particle filter of claim 1, wherein:
the sloped surfaces are substantially conical.

4. The charged particle filter of claim 3, wherein:
the radius of the substantially conical surfaces is relative to the angle.

5. The charged particle filter of claim 1, wherein:
the sloped surfaces comprise an angle in the range of 5-45°.

6. The charged particle filter of claim 5, wherein:
the sloped surfaces comprise an angle of 15.4°.

7. The charged particle filter of claim 1, wherein:
the bore comprises a field of view on the platform defined by a diameter of a second aperture on a side of the bore facing the platform.

8. The charged particle filter of claim 7, wherein:
the field of view is about 128 mm in diameter.

9. The charged particle filter of claim 1, wherein:
the magnetic field gradient comprises a range of about 1000 gauss-5000 gauss.

10. The charged particle filter of claim 1, further comprising:
one or more inserts configured to fill space between the magnets.

11. The charged particle filter of claim 1, further comprising:
a flux ring comprising a geometry that properly positions the magnets for the slope angle.

12. An electron-beam additive manufacturing instrument, comprising:
an electron beam source configured to produce an electron beam;
a platform configured as a support upon which the electron beam additive manufacturing instrument builds a product in response to the electron beam;
a detector configured to produce a signal in response to one or more X-ray photons released from the product in response to the electron beam; and
a charged particle filter configured to deflect one or more charged particles released from the product in response to the electron beam away from the detector, wherein the charged particle filter comprises a plurality of magnets, each comprising a surface sloped at an angle relative to a plane defined by a line from a center of a field of view on a detector to the center of a field of view on a platform, wherein the sloped surfaces are positioned to form a bore that comprises a magnetic field gradient that is strongest at a first aperture on a side of the bore proximate to the detector.

13. The electron-beam additive manufacturing instrument of claim 12, wherein:
the sloped surfaces are substantially planar.

14. The electron-beam additive manufacturing instrument of claim 12, wherein:
the sloped surfaces are substantially conical.

15. The electron-beam additive manufacturing instrument of claim 14, wherein:
the radius of the substantially conical surfaces is relative to the angle.

16. The electron-beam additive manufacturing instrument of claim 12, wherein:
the sloped surfaces comprise an angle in the range of 5-45°.

17. The electron-beam additive manufacturing instrument of claim 16, wherein:
the sloped surfaces comprise an angle of 15.4°.

18. The electron-beam additive manufacturing instrument of claim 12, wherein:
the bore comprises a field of view on the platform defined by a diameter of a second aperture on a side of the bore facing the platform.

19. The electron-beam additive manufacturing instrument of claim 18, wherein:
the field of view is about 128 mm in diameter.

20. The electron-beam additive manufacturing instrument of claim 12, wherein:
the magnetic field gradient comprises a range of about 1000 gauss-5000 gauss.

21. The electron beam melting instrument of claim 12, further comprising:
one or more inserts configured to that fill space between the magnets.

22. The electron beam melting instrument of claim 12, further comprising:
a flux ring comprising a geometry that properly positions the magnets for the slope angle.
